(19) United States
(12) Patent Application Publication
(10) Pub. No.: US 2026/0082783 A1
(43) Pub. Date: Mar. 19, 2026

(54) DISPLAY APPARATUS HAVING AN ELECTRO-STATIC DISCHARGE CIRCUIT

(71) Applicant: LG Display Co., Ltd., Seoul (KR)

(72) Inventors: Sang Il SHIN, Paju-si (KR); Jae Chang KANG, Paju-si (KR); Tae Kyun KIM, Paju-si (KR); Ji Su CHOI, Paju-si (KR)

(73) Assignee: LG Display Co., Ltd., Seoul (KR)

(21) Appl. No.: 19/334,243

(22) Filed: Sep. 19, 2025

(30) Foreign Application Priority Data
Sep. 19, 2024 (KR) 10-2024-0126701

(51) Int. Cl. H10K 59/131; G09G 3/3225; H10K 59/121

(52) U.S. Cl. CPC H10K 59/131; G09G 3/3225; H10K 59/1213; G09G 2330/06

(57) ABSTRACT

A display apparatus includes a device substrate having a display area and a bezel area with an organic insulating layer disposed on the display area of the device substrate, and a plurality of inorganic insulating layers disposed between the device substrate and the organic insulating layer. The plurality of inorganic insulating layers, as well as a plurality of signal wirings, extend from the display area to on the bezel area of the device substrate. Also, an electro-static discharge (ESD) circuit is disposed on the bezel area, the electro-static discharge circuit including a first ESD transistor electrically connected to a second ESD transistor and a signal wiring of the plurality of signal wirings with the ESD circuit preventing damage in pixel area due to a static electricity.

### CROSS-REFERENCE TO RELATED APPLICATIONS

This application claims priority to Korean Patent Application No. 10-2024-0126701, filed in the Republic of Korea on Sep. 19, 2024, which is hereby incorporated by reference as if fully set forth herein.

### BACKGROUND OF THE DISCLOSURE

### Field of the Disclosure

The present disclosure relates to a display apparatus in which an electro-static discharge circuit is disposed on a bezel area.

### Discussion of the Related Art

Generally, a display apparatus provides an image to a user with the display apparatus including a light-emitting device. The light-emitting device can emit light displaying a specific color with the light-emitting device disposed between a first electrode and a second electrode. The light-emitting device can also be disposed on a display area, and a bezel area can be disposed outside the display area.

Further, at least one electro-static discharge circuit (ESD circuit) can be disposed on the bezel area, and the electro-static discharge circuit can be electrically connected to one of signal wirings extending from the display area toward the bezel area. Thus, in the display apparatus, damage of the light-emitting device and damage of a driving circuit electrically connected to the light-emitting device due to a static electricity can be prevented.

### SUMMARY OF THE DISCLOSURE

Accordingly, the present disclosure is directed to a display apparatus substantially obviating one or more problems due to limitations and disadvantages of the related art. An object of the present disclosure is to provide a display apparatus capable of preventing the damage of the electro-static discharge circuit due to moisture and oxygen. Another object of the present disclosure is to provide a display apparatus capable of suppressing electrolytic corrosion reaction of electrodes constituting the electro-static discharge circuit.

Additional advantages, objects, and features of the disclosure will be set forth in part in the description which follows and in part will become apparent to those having ordinary skill in the art upon examination of the following or can be learned from practice of the disclosure. The objectives and other advantages of the disclosure can be realized and attained by the structure particularly pointed out in the written description and claims hereof as well as the appended drawings.

To achieve these objects and other advantages and in accordance with the purpose of the present disclosure, as embodied and broadly described herein, there is provided a display apparatus including a device substrate. An organic insulating layer is disposed on a display area of the device substrate. A plurality of inorganic insulating layers is disposed between the device substrate and the organic insulating layer. The plurality of inorganic insulating layer extends on a bezel area of the device substrate. An electro-static discharge circuit is disposed on the bezel area. The electro-static discharge circuit includes an ESD transistor. An ESD gate electrode, a first ESD electrode, and a second ESD electrode of the ESD transistor are disposed between the plurality of inorganic insulating layers with the second ESD electrode disposed on a same layer as the first ESD electrode.

Also, a voltage wiring can be disposed on the bezel area. The voltage wiring can be electrically connected to the first ESD electrode, and can be disposed on a different layer from the first ESD electrode and the second ESD electrode. In addition, the plurality of inorganic insulating layer can be disposed between the device substrate and the voltage wiring.

Next, a driving circuit can be disposed between the device substrate and the organic insulating layer with the driving circuit overlapping the display area. The driving circuit can include a first thin film transistor, and the first thin film transistor can include a first gate electrode, a first drain electrode, and a first source electrode. The first gate electrode can be disposed on a same layer as the ESD gate electrode, and the first drain electrode and the first source electrode can be disposed on a different layer from the first ESD electrode and the second ESD electrode. The first drain electrode and the first source electrode can also be disposed between the plurality of inorganic insulating layers and the organic insulating layer. Further, a first semiconductor pattern of the first thin film transistor can be disposed on a same layer as an ESD semiconductor pattern of the ESD transistor.

In addition, the driving circuit can include a second thin film transistor, and the second thin film transistor can include a second semiconductor pattern, a second gate electrode, a second drain electrode, and a second source electrode. The second gate electrode can be disposed on a different layer from the first gate electrode. The second drain electrode and the second source electrode can be disposed on a same layer as the first drain electrode and the first source electrode. The second semiconductor pattern can be disposed on a different layer from the first semiconductor pattern.

In another embodiment, there is provided a display apparatus including a device substrate. A light-emitting device and a driving circuit are disposed on a display area of the device substrate, and the driving circuit is electrically connected to the light-emitting device. A signal wiring is electrically connected to the driving circuit and extends on a bezel area of the device substrate. An electro-static discharge circuit is disposed on the bezel area, and includes a high potential ESD transistor and a low potential ESD transistor. A first high potential ESD electrode of the high potential ESD transistor is electrically connected to a high potential voltage wiring. A first low potential ESD electrode of the low potential ESD transistor is electrically connected to a low potential voltage wiring. A second high potential ESD electrode of the high potential ESD transistor and a second low potential ESD electrode of the low potential ESD transistor are electrically connected to the signal wiring. A first inorganic insulating layer is disposed between the second high potential ESD electrode and the high potential voltage wiring, between the second low potential ESD electrode and the low potential voltage wiring, and between the first high potential ESD electrode and the first low potential ESD electrode.

Further, the second high potential ESD electrode and the second low potential ESD electrode can be disposed on a different layer from the signal wiring and the low potential voltage wiring can be disposed on a same layer as the high potential voltage wiring. The first high potential ESD electrode and the first low potential ESD electrode can also be disposed on a same layer as the high potential voltage wiring and the low potential voltage wiring.

Also, an organic insulating layer can be disposed between the driving circuit and the light-emitting device, a second inorganic insulating layer can be disposed between the device substrate and the organic insulating layer, and the second inorganic insulating layer can include a same material as the first inorganic insulating layer. In addition, the driving circuit can include a plurality of thin film transistors, and a drain electrode and a source electrode of some of the thin film transistors can be disposed between the second inorganic insulating layer and the organic insulating layer. Also, a pad area can be disposed in the bezel area and the electro-static discharge circuit can be disposed between the display area and the pad area.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a view schematically showing a display apparatus according to an embodiment of the present disclosure;

FIG. 2 is a view showing a circuit of a pixel area in the display apparatus according to the embodiment of the present disclosure;

FIG. 3 is a view showing a cross-section of a pixel area in the display apparatus according to the embodiment of the present disclosure;

FIG. 4 is an enlarged view of the K1 region in FIG. 1;

FIG. 5 is a view explaining an operation of an electro-static discharge circuit in the display apparatus according to the embodiment of the present disclosure;

FIG. 6 is a view taken along I-I′ of FIG. 4;

FIG. 7 is a view taken along II-II′ of FIG. 4;

FIG. 8 is a view taken along III-III′ of FIG. 4; and

FIGS. 9 to 24 are views showing the display apparatus according to another embodiment of the present disclosure.

### DETAILED DESCRIPTION OF THE EMBODIMENTS

Hereinafter, details related to the above objects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure can be embodied in other forms and is not limited to the embodiments described below.

In addition, the same or extremely similar elements can be designated by the same reference numerals throughout the specification and in the drawings, the lengths and thickness of layers and regions can be exaggerated for convenience. It will be understood that, when a first element is referred to as being “on” a second element, although the first element can be disposed on the second element to come into contact with the second element, a third element can be interposed between the first element and the second element.

Here, terms such as, for example, “first” and “second” can be used to distinguish any one element with another element. However, the first element and the second element can be arbitrary named according to the convenience of those skilled in the art without departing the technical sprit of the present disclosure.

Also, terms used in the specification of the present disclosure are merely used in order to describe particular embodiments, and are not intended to limit the scope of the present disclosure. For example, an element described in the singular form is intended to include a plurality of elements unless the context clearly indicates otherwise. In addition, in the specification of the present disclosure, it will be further understood that the terms “comprises” and “includes” specify the presence of stated features, integers, steps, operations, elements, components, and/or combinations thereof, but do not preclude the presence or addition of one or more other features, integers, steps, operations, elements, components, and/or combinations. Also, unless ‘directly’ is used, the terms “connected” and “coupled” can include two components being “connected” or “coupled” through one or more other components located between the two components.

Further, unless otherwise defined, all terms (including technical and scientific terms) used herein have the same meaning as commonly understood by one of ordinary skill in the art to which example embodiments belong. Also, it will be further understood that terms, such as those defined in commonly used dictionaries, should be interpreted as having a meaning consistent with their meaning in the context of the relevant art and should not be interpreted in an idealized or overly formal sense unless expressly so defined herein. Also, the features of various embodiments of the present disclosure can be partially or entirely coupled to or combined with each other and can be interlocked and operated in technically various ways, and the embodiments can be carried out independently of or in association with each other. Also, the term “can” used herein includes all meanings and definitions of the term “may.”

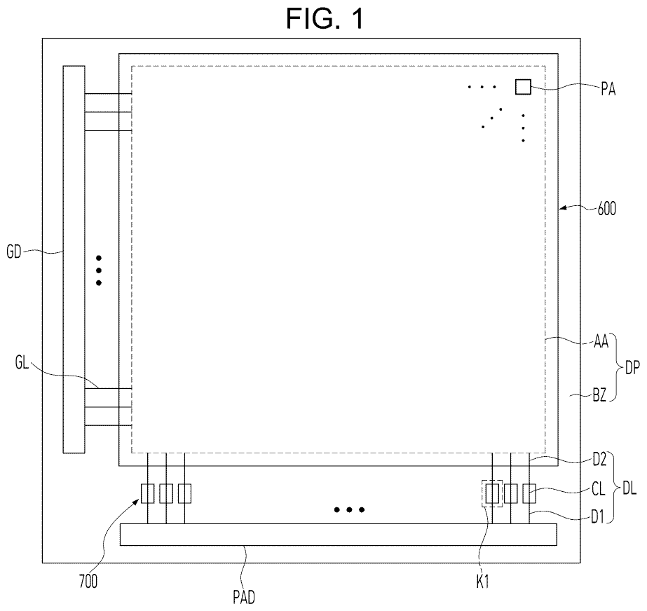

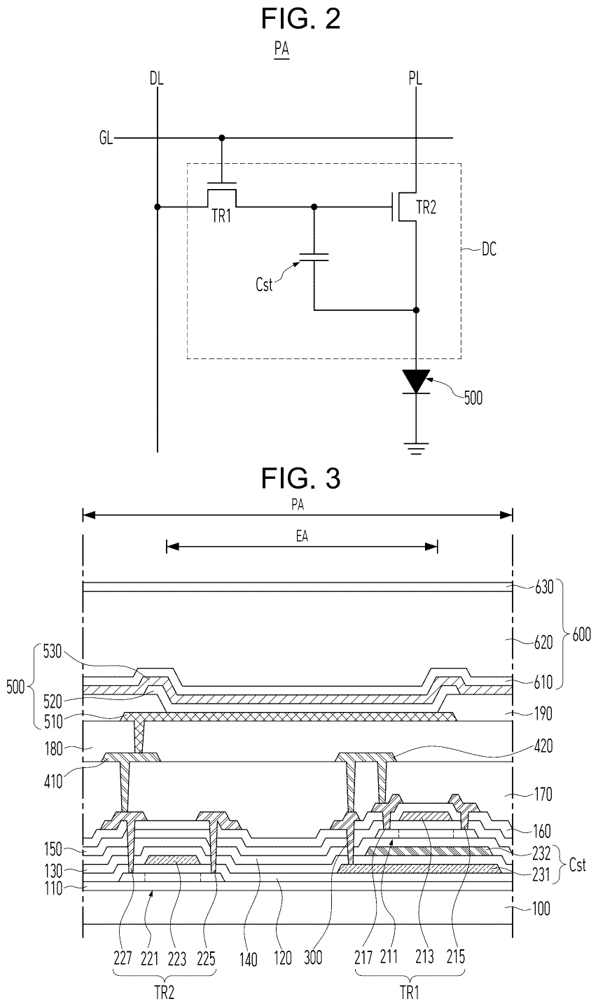

FIG. 1 is a view schematically showing a display apparatus according to an embodiment of the present disclosure. FIG. 2 is a view showing a circuit of a pixel area in the display apparatus according to the embodiment of the present disclosure. FIG. 3 is a view showing a cross-section of a pixel area in the display apparatus according to the embodiment of the present disclosure. Referring to FIGS. 1 to 3, the display apparatus can include a display panel DP including a display area AA and a bezel area BZ. The display panel DP can generate an image in the active area AA. which can include a plurality of pixel areas PA. Various signals can be transmitted to each pixel area PA through signal wirings, which can include gate lines GL applying a gate signal, data lines DL applying a data signal and power voltage supply lines PL supplying a first power voltage. The first power voltage can have a relative high potential as compared to a signal ground or another power line. For example, the first power voltage can be a positive power voltage (VDD).

Each of the pixel areas PA can realize a specific color. For example, a light-emitting device 500 (see FIG. 2) can be disposed in each pixel area PA. The light-emitting device 500 can emit light displaying a specific color, such as blue, green, yellow, red, and white. Further, the light-emitting device 500 can include a first electrode 510, a light-emitting unit 520, and a second electrode 530, which are sequentially stacked.

The first electrode 510 and the second electrode 530 can include a conductive material. The second electrode 530 can include a different material from the first electrode 510 to allow a transmittance of the second electrode 530 to be higher than a transmittance of the first electrode 510. The first electrode 510 can include a material having higher reflectance than the second electrode 530. For example, the first electrode 510 can include a metal, such as aluminum (Al) and silver (Ag), and the second electrode 530 can be a transparent electrode made of a transparent conductive material, such as ITO and IZO. The first electrode 510 can also have a multi-layer structure. For example, the first electrode 510 can have a structure in which a reflective electrode made of a metal is disposed between transparent electrodes made of a transparent conductive material, such as ITO and IZO. The second electrode 530 can have a work-function lower than the first electrode 510, which can aid the first electrode 510 to function as an anode electrode and the second electrode 530 to function as a cathode electrode.

Further, the light-emitting unit 520 can generate light having luminance corresponding to a voltage difference between the first electrode 510 and the second electrode 530. For example, the light-emitting unit 520 can include at least one emission material layer (EML). The emission material layer, in turn, can include an organic emission material, an inorganic emission material, or a hybrid emission material. Thus, the display apparatus can be an organic light-emitting display apparatus including an organic emission material, and light generated by the light-emitting unit 520 can be emitted through the second electrode 530.

The light-emitting unit 520 can further include at least one functional layer, which can smoothly move holes and/or electrons. For example, the function layer can be one of a hole injection layer (HIL), a hole transport layer (HTL), an electron transport layer (ETL) and an electron injection layer (EIL). Thus, in the display apparatus according to the embodiment of the present disclosure, the efficiency of the light-emitting unit 520 can be improved.

Further, a driving circuit DC for controlling the operation of the light-emitting device 500 can be disposed in each pixel area PA. The driving circuit DC can include a first thin film transistor TR1, a second thin film transistor TR2, and a storage capacitor Cst with the driving circuit DC electrically connected to the light-emitting device 500. As shown in FIG. 2, the driving circuit DC can be electrically connected to the signal wirings GL, DL, and PL. For example, the driving circuit DC can be electrically connected to one of the gate lines GL, one of the data lines DL, and one of the power voltage supply lines PL.

In operation, the driving circuit DC can supply a driving current corresponding to the data signal to the light-emitting device 500 of the corresponding pixel area PA according to the gate signal for one frame. The first thin film transistor TR1 of each pixel area PA, in turn, can transmit the data signal to the second thin film transistor TR2 of the corresponding pixel area PA according to the gate signal. Accordingly, the first thin film transistor TR1 can function as a switching thin film transistor.

As is shown in FIG. 3, the first thin film transistor TR1 can include a first semiconductor pattern 211, a first gate electrode 213, a first drain electrode 215, and a first source electrode 217. The first gate electrode 213 can be electrically connected to the corresponding gate line GL, and the first drain electrode 215 can be electrically connected to the corresponding data line DL. Also, the first semiconductor pattern 211 can include a semiconductor material. For example, the first semiconductor pattern 211 can include an oxide semiconductor, such as IGZO. The first semiconductor pattern 211 can also include a first drain region, a first channel region, and a first source region with the first channel region disposed between the first drain region and the first source region. The first drain region and the first source region can have a smaller resistance than the first channel region to allow the first drain region and the first source region to include a conductive region of an oxide semiconductor. In contrast, the first channel region can be a region of an oxide semiconductor not as conductive.

Further, the first gate electrode 213 can be disposed on a portion of the first semiconductor pattern 211 to overlap the first channel region of the first semiconductor pattern 211, and the first drain region and the first source region of the first semiconductor pattern 211 can be disposed outside the first gate electrode 213. The first gate electrode 213 can include a conductive material. For example, the first gate electrode 213 can include a metal, such as aluminum (Al), chrome (Cr), copper (Cu), molybdenum (Mo), titanium (Ti), and tungsten (W). The first gate electrode 213 can be spaced apart and insulated from the first semiconductor pattern 211. Further, the first source region of the first semiconductor pattern 211 can be electrically connected to the first drain region of the first semiconductor pattern 211 via the first channel region.

Also, the first drain electrode 215 can be electrically connected to the first drain region of the first semiconductor pattern 211 and can include a conductive material. For example, the first drain electrode 215 can include a metal, such as aluminum (Al), chrome (Cr), copper (Cu), molybdenum (Mo), titanium (Ti), and tungsten (W). The first drain electrode 215 can also include a different material from the first gate electrode 213, can be disposed on a different layer from the first gate electrode 213, and can be insulated from the first gate electrode 213.

Further, the first source electrode 217 can be electrically connected to the first source region of the first semiconductor pattern 211, and can include a conductive material. For example, the first source electrode 217 can include a metal, such as aluminum (Al), chrome (Cr), copper (Cu), molybdenum (Mo), titanium (Ti), and tungsten (W). The first source electrode 217 can also include a different material from the first gate electrode 213, and be disposed on a different layer from the first gate electrode 213. The first source electrode 217 can also be insulated from the first gate electrode 213, be disposed on a same layer as the first drain electrode 215, include a same material as the first drain electrode 215, and be formed by a same process as the first drain electrode 215. Still further, the first source electrode 217 can be formed simultaneously with the first drain electrode 215 while spaced apart from the first drain electrode 215.

In addition, the second thin film transistor TR2 can generate the driving current corresponding to the data signal, and thus function as a driving thin film transistor. The second thin film transistor TR2 can also include a second semiconductor pattern 221, a second gate electrode 223, a second drain electrode 225, and a second source electrode 227. The second gate electrode 223 can be electrically connected to the first source electrode 217 of the corresponding pixel area PA while the second drain electrode 225 can be electrically connected to the corresponding power voltage supply line PL. The light-emitting device 500 can also be electrically connected to the second source electrode 227 of the corresponding pixel area PA.

Further, the second semiconductor pattern 221 can include a semiconductor material, and in various embodiments can include a different material from the first semiconductor pattern 211. For example, the second semiconductor pattern 221 can include a low-temperature polycrystalline silicon (LTPS). The second semiconductor pattern 221 can also be disposed on a different layer from the first semiconductor pattern 211 with the second semiconductor pattern 221 formed by a process different from the first semiconductor pattern 211.

Also, the second semiconductor pattern 221 can include a second drain region, a second channel region, and a second source region with the second channel region disposed between the second drain region and the second source region. Also, the second drain region and the second source region can have a smaller resistance than the second channel region. For example, the second drain region and the second source region can include a region doped with conductive impurities while the second channel region can include a region not doped with conductive impurities.

In addition, the second gate electrode 223 can be disposed on a portion of the second semiconductor pattern 221 so as to overlap the second channel region of the second semiconductor pattern 221. In contrast, the second drain region and the second source region of the second semiconductor pattern 221 can be disposed to not overlap the second gate electrode 223. The second gate electrode 223 can also be used as a mask pattern in a process of doping conductive impurities in the second drain region and the second source region of the second semiconductor pattern. The second gate electrode 223 can also include a conductive material. For example, the second gate electrode 223 can include a metal, such as aluminum (Al), chrome (Cr), copper (Cu), molybdenum (Mo), titanium (Ti), and tungsten (W). The second gate electrode 223 can include a different material from the first gate electrode 213. The second gate electrode 223 can also be disposed on a different layer from the first gate electrode 213 and be formed by a process different from the first gate electrode 213. The second gate electrode 223 can also be spaced apart from, and insulated from, the second semiconductor pattern 221. The second channel region of the second semiconductor pattern 221 can also pass an electrical current corresponding to a voltage applied to the second gate electrode 223.

Further, the second drain electrode 225 can be electrically connected to the second drain region of the second semiconductor pattern 221, and can include a conductive material. For example, the second drain electrode 225 can include a metal, such as aluminum (Al), chrome (Cr), copper (Cu), molybdenum (Mo), titanium (Ti), and tungsten (W). The second drain electrode 225 can also include a different material from the second gate electrode 223, be disposed on a different layer from the second gate electrode 223, and be insulated from the second gate electrode 223.

Also, the second drain electrode 225 can be disposed on a same layer as the first drain electrode 215, can include a same material as the first drain electrode 215, and simultaneously be formed by a same process as the first drain electrode 215. Thus, in the display apparatus according to the embodiment of the present disclosure, the process efficiency can be improved.

In addition, the second source electrode 227 can be electrically connected to the second source region of the second semiconductor pattern 221, and can include a conductive material. For example, the second source electrode 227 can include a metal, such as aluminum (Al), chrome (Cr), copper (Cu), molybdenum (Mo), titanium (Ti), and tungsten (W). The second source electrode 227 can include a different material from the second gate electrode 223, be disposed on a different layer from the second gate electrode 223 and be insulated from the second gate electrode 223. Also, the second source electrode 227 can be disposed on a same layer as the second drain electrode 225, can include a same material as the second drain electrode 225, and can be simultaneously formed by a same process as the second drain electrode 225.

In operation, the storage capacitor Cst can maintain a voltage applied to the second gate electrode 223 of the corresponding pixel area PA for one frame. The storage capacitor Cst can be electrically connected to the second gate electrode 223 and the second source electrode 227 of the corresponding pixel area PA. The storage capacitor Cst can have a stacked structure and can include a first capacitor electrode 231 and a second capacitor electrode 232 disposed on the first capacitor electrode 231.

The first capacitor electrode 231 can include a conductive material and be electrically connected to first source electrode 217. The first capacitor electrode 231 can include a metal, such as aluminum (Al), chrome (Cr), copper (Cu), molybdenum (Mo), titanium (Ti), and tungsten (W). The first capacitor electrode 231 can be electrically connected to the second gate electrode 223 of the corresponding pixel area PA. The first capacitor electrode 231 can also be disposed on a same layer as the second gate electrode 223 of the corresponding pixel area PA, can include a same material as the second gate electrode 223 of the corresponding pixel area PA, and simultaneously be formed by a same process as the second gate electrode 223 of the corresponding pixel area PA

Further, the second capacitor electrode 232 can overlap a portion of the first capacitor electrode 231 in the corresponding pixel area PA, and can include a conductive material. For example, the second capacitor electrode 232 can include a metal, such as aluminum (Al), chrome (Cr), copper (Cu), molybdenum (Mo), titanium (Ti), and tungsten (W). The storage capacitor Cst can also be disposed between a device substrate 100 and the first semiconductor pattern 211 of the corresponding pixel area PA with the second capacitor electrode 232 disposed between the first capacitor electrode 231 and the first semiconductor pattern 211 of the corresponding pixel area PA. Also, the first semiconductor pattern 211 can overlap the first capacitor electrode 231 and the second capacitor electrode 232 of the corresponding pixel area PA. Thus, external light travelling toward the first semiconductor pattern 211 through the device substrate 100 can be blocked by the capacitor electrodes 231 and 232 of the corresponding pixel area PA. Therefore, the malfunction of the first thin film transistor TR1 in each pixel area PA due to the external light can be prevented while an area occupied by the driving circuit DC can be minimized.

Also, the driving circuit DC and the light-emitting device 500 can be disposed on the device substrate 100 such that the device substrate 100 supports the driving circuit DC and the light-emitting device 500 of each pixel area PA. The device substrate 100 can include an insulating material, such as glass or plastic. Also, various insulating layers for preventing unnecessary electrical connection can be disposed on the device substrate 100. For example, a lower buffer layer 110, a lower gate insulating layer 120, a lower interlayer insulating layer 130, an upper buffer layer 140, an upper gate insulating layer 150, an upper interlayer insulating layer 160, a lower planarization layer 170, an upper planarization layer 180, and a bank insulating layer 190 can be disposed on the device substrate 100.

The lower buffer layer 110 can be disposed close to the device substrate 100, and the driving circuit DC can be disposed on the lower buffer layer 110. The lower buffer layer 110 can prevent the pollution due to the device substrate 100 in a process of forming the driving circuit DC of each pixel area PA. The lower buffer layer 110 can include an insulating material. For example, the lower buffer layer 110 can be an inorganic insulating layer made of an inorganic insulating material, such as silicon oxide (SiOx) and silicon nitride (SiNx). The lower buffer layer 110 can also have a multi-layer structure. For example, the lower buffer layer 110 can have a stacked structure of an inorganic insulating layer made of silicon oxide (SiOx) and an inorganic insulating layer made of silicon nitride (SiNx).

Also, the lower gate insulating layer 120 can be disposed on the lower buffer layer 110, and can cover the second semiconductor pattern 221 of each pixel area PA. Thus, the second gate electrode 223 can be insulated from the second semiconductor pattern 221 of the corresponding pixel area PA by the lower gate insulating layer 120. The second gate electrode 223 and the first capacitor electrode 231 can also be disposed on the lower gate insulating layer 120. Also, the lower gate insulating layer 120 can include an insulating material, such as an inorganic insulating layer made of an inorganic insulating material, such as silicon oxide (SiOx) and silicon nitride (SiNx).

In addition, the lower interlayer insulating layer 130 can be disposed on the lower gate insulating layer 120 such that the second capacitor electrode 232 can be spaced apart from the first capacitor electrode 231 of the corresponding pixel area PA by the lower interlayer insulating layer 130. The lower interlayer insulating layer 130 can cover the second gate electrode 223 and the first capacitor electrode 231, and the second capacitor electrode 232 can be disposed on the lower interlayer insulating layer 130. The lower interlayer insulating layer 130 can include an insulating material, such as an inorganic insulating layer made of an inorganic insulating material, such as silicon oxide (SiOx) and silicon nitride (SiNx).

Next, the upper buffer layer 140 can be disposed on the lower interlayer insulating layer 130, and can cover the second capacitor electrode 232. The first semiconductor pattern 211 can be disposed on the upper buffer layer 140. Accordingly, the first semiconductor pattern 211 can be spaced apart from the second capacitor electrode 232 The upper buffer layer 140 can include an insulating material, such as an inorganic insulating layer made of an inorganic insulating material, such as silicon oxide (SiOx) and silicon nitride (SiNx).

Also, the upper gate insulating layer 150 can be disposed on the upper buffer layer 140, and the first gate electrode 213 can be insulated from the first semiconductor pattern 211 of the corresponding pixel area PA by the upper gate insulating layer 150. The upper gate insulating layer 150 can also cover the first semiconductor pattern 211 of each pixel area PA, and the first gate electrode 213 can be disposed on the upper gate insulating layer 150. The upper gate insulating layer 150 can include an insulating material, such as an inorganic insulating layer made of an inorganic insulating material.

Next, the upper interlayer insulating layer 160 can be disposed on the upper gate insulating layer 150. The first drain electrode 215 and the first source electrode 217 can be insulated from the first gate electrode 213 of the corresponding pixel area PA by the upper interlayer insulating layer 160. The upper interlayer insulating layer 160 can cover the first gate electrode 213, and the first drain electrode 215, the first source electrode 217, the second drain electrode 225, and the second source electrode 227 can be disposed on the upper interlayer insulating layer 160. Also, the second drain electrode 225 can be connected to the second drain region of the corresponding pixel area PA by penetrating the lower gate insulating layer 120, the lower interlayer insulating layer 130, the upper buffer layer 140, the upper gate insulating layer 150, and the upper interlayer insulating layer 160. Similarly, the second source electrode 227 can be connected to the second source region of the corresponding pixel area PA by penetrating the lower gate insulating layer 120, the lower interlayer insulating layer 130, the upper buffer layer 140, the upper gate insulating layer 150, and the upper interlayer insulating layer 160. The upper interlayer insulating layer 160 can include an insulating material, such as an inorganic insulating layer made of an inorganic insulating material.

Further, the lower planarization layer 170 can be disposed on the upper interlayer insulating layer 160, and the upper planarization layer 180 can be disposed on the lower planarization layer 170. A thickness difference due to the driving circuit DC can be removed by the lower planarization layer 170 and the upper planarization layer 180. Also, the first drain electrode 215, the first source electrode 217, the second drain electrode 225, and the second source electrode 227 can be covered by the lower planarization layer 170. An upper surface of the upper planarization layer 180 opposite to the device substrate 100 can be flat, and can be parallel to the upper surface of the device substrate 100. The lower planarization layer 170 and the upper planarization layer 180 can include an insulating material. Also, the lower planarization layer 170 and the upper planarization layer 180 can include a different material from the upper interlayer insulating layer 160. The lower planarization layer 170 and the upper planarization layer 180 can include a material having a relatively high fluidity, such as an organic insulating layer made of an organic insulating material. The upper planarization layer 180 can also include a different material from the lower planarization layer 170. Thus, in the display apparatus according to the embodiment of the present disclosure, a thickness difference due to the driving circuit DC can be effectively removed.

In addition, the light-emitting device 500 can be disposed on the upper planarization layer 180 with the first electrode 510, the light-emitting unit 520, and the second electrode 530 can be sequentially stacked on the upper surface of the upper planarization layer 180. The light-emitting device 500 of each pixel area PA can be controlled independently from the light-emitting device 500 of an adjacent pixel area PA. The first electrode 510 of each pixel area PA can be insulated from the first electrode 510 of the adjacent pixel area PA by the bank insulating layer 190. The bank insulating layer 190 can be disposed on the upper planarization layer 180. The bank insulating layer 190 can include an insulating material, such as an organic insulating layer made of an organic insulating material.

Also, the bank insulating layer 190 can define an emission area EA in each pixel area PA, and the light-emitting device 500 of each pixel area PA can be disposed on the emission area EA defined in the corresponding pixel area PA by the bank insulating layer 190. The bank insulating layer 190 can also partially expose the first electrode 510 of each pixel area PA such that an edge of the first electrode 510 is be covered by the bank insulating layer 190. The light-emitting unit 520 and the second electrode 530 can then be stacked on a portion of the corresponding first electrode 510 exposed by the bank insulating layer 190. Thus, in the display apparatus according to the embodiment of the present disclosure, light cannot be generated in a region disposed outside the emission area EA.

Also, the first electrode 510 can be electrically connected to the driving circuit DC of the corresponding pixel area PA by a region overlapping with the bank insulating layer 190, a portion of the first electrode 510 overlapping with the emission area EA defined in each pixel area PA can be parallel to the upper surface of the upper planarization layer 180, and can be in direct contact with the upper surface of the upper planarization layer 180 in the emission area EA defined in the corresponding pixel area PA. Thus, luminance deviation due to the generation location of the light emitted from the light-emitting device 500 can be prevented.

Further, first intermediate electrodes 410 electrically connecting the first electrode 510 to the driving circuit DC can be disposed between the lower planarization layer 170 and the upper planarization layer 180. For example, the first electrode 510 can be electrically connected to one of the first intermediate electrodes 410, and each of the first intermediate electrodes 410 can be electrically connected to the second source electrode 227. The first intermediate electrodes 410 can include a conductive material. For example, the first intermediate electrodes 410 can include a metal, such as aluminum (Al), chrome (Cr), copper (Cu), molybdenum (Mo), titanium (Ti), and tungsten (W). Thus, the light-emitting device 500 of each pixel area PA can be stably connected to the driving circuit DC of the corresponding pixel area PA.

Still further, a second intermediate electrode 420 can be disposed between the lower planarization layer 170 and the upper planarization layer 180 of each pixel area PA. The second intermediate electrode 420 can include a conductive material, and can include a same material as the first intermediate electrode 410. Also, the first source electrode 217 can be electrically connected to the first capacitor electrode 231 of the corresponding pixel area PA through the second intermediate electrode 420 of the corresponding pixel area PA. Thus, a process of electrically connecting between the first source electrode 217 and the first capacitor electrode 231 in each pixel area PA can be simplified.

Also, a capacitor connection electrode 300 can be disposed between the first capacitor electrode 231 and the second intermediate electrode 420. The capacitor connection electrode 300 can be disposed on a same layer as the first source electrode 217 of the corresponding pixel area PA, i.e., between the upper interlayer insulating layer 160 and the lower planarization layer 170. The capacitor connection electrode 300 can also include a same material as the first source electrode 217, and can be formed simultaneously by a same process as the first source electrode 217. Thus, the first source electrode 217 of each pixel area PA can be stably connected to the first capacitor electrode 231 of the corresponding pixel area PA.

In addition, the light emitted from the light-emitting device 500 of each pixel area PA can display a different color from the light emitted from the light-emitting device 500 of an adjacent pixel area PA. For example, the light-emitting unit 520 of each pixel area PA can include a different material from the light-emitting unit 520 of the adjacent pixel area PA, and can be spaced apart from the light-emitting unit 520 of the adjacent pixel area PA. The light-emitting unit 520 can also include an end portion disposed on the bank insulating layer 190.

Further, a second power voltage different from the first power voltage can be applied to the second electrode 530 of each pixel area PA. The second power voltage can have a relatively low potential as compared to different from the first power voltage. For example, the second power voltage can be a negative power voltage (VSS). The second electrode 530 of each pixel area PA can be electrically connected to the second electrode 530 of an adjacent pixel area PA, can include a same material as the second electrode 530 of the adjacent pixel area PA, and can be simultaneously formed by a same process as the second electrode 530 of the adjacent pixel area PA. For example, the second electrode 530 can be formed simultaneously with the second electrode 530 of the adjacent pixel area PA. The second electrode 530 can also be in direct contact with the second electrode 530 of the adjacent pixel area PA. Thus, a process of forming the second electrode 530 can be simplified while the luminance of the light generated from the light-emitting unit 520 of each pixel area PA can be adjusted by the data signal applied to the driving circuit DC of the corresponding pixel area PA.

Next, an encapsulation structure 600 can be disposed on the light-emitting device 500 of each pixel area PA. The encapsulation structure 600 can prevent the damage of the light-emitting devices 500 due to external moisture and impact. The encapsulation structure 600 can have a multi-layer structure. For example, the encapsulation structure 600 can include a first encapsulating layer 610, a second encapsulating layer 620, and a third encapsulating layer 630, which are sequentially stacked on the second electrode 530 of each pixel area PA. The first encapsulating layer 610, the second encapsulating layer 620, and the third encapsulating layer 630 can include an insulating material. The second encapsulating layer 620 can include a different material from the first encapsulating layer 610 and the third encapsulating layer 630. For example, the first encapsulating layer 610 and the third encapsulating layer 630 can be an inorganic insulating layer made of an inorganic insulating material, and the second encapsulating layer 620 can be an organic insulating layer made of an organic insulating material. Thus, in the display apparatus according to the embodiment of the present disclosure, the damage of the light-emitting devices 500 due to the external moisture and impact can be effectively prevented. A thickness difference due to the light-emitting device 500 can be removed by the second encapsulating layer 620. For example, the second encapsulating layer 620 can have a larger thickness than the first encapsulating layer 610 and the third encapsulating layer 630. An upper surface of the third encapsulating layer 630 opposite to the device substrate 100 can be flat, and the upper surface of the third encapsulating layer 630 can be parallel to the upper surface of the device substrate 100.

As stated above, display panel DP can include a display area AA in which the pixel areas PA are disposed and a bezel area BZ disposed outside and surrounding the display area AA. Each of the signal wirings GL, DL, and PL can extend on the bezel area BZ with a gate driver GD electrically connected to the gate lines GL, a data driver electrically connected to the data lines DL, and a power unit electrically connected to the power voltage supply lines PL. At least one of the gate driver GD, the data driver, and the power unit can be disposed on the bezel area BZ. For example, the display apparatus can be a GIP (Gate In Panel) type display apparatus in which the gate driver GD is formed on the bezel area BZ of the device substrate 100.

Also, a pad area PAD in which an external signal is applied can be disposed within the bezel area BZ. For example, the data driver disposed outside the display panel DP can apply the data signal through the pad area PAD. Each of the data lines DL can be electrically connected to the pad area PAD, and the data lines DL can extend in a different direction from the gate lines GL. For example, the gate driver GD can be disposed on a first side of the display area AA, and the pad area PAD can be disposed on a second side of the display area perpendicular to the first side. Thus, in the display apparatus according to the embodiment of the present disclosure, the data signal applied through the data lines DL may not be distorted by the gate signal applied through the gate lines GL.

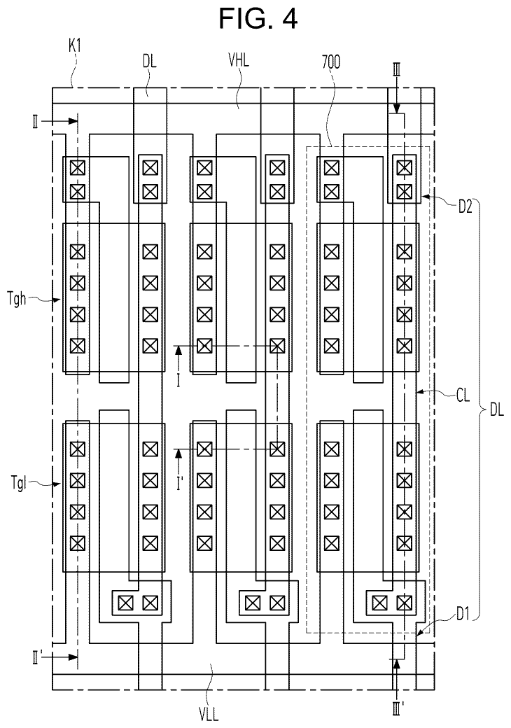

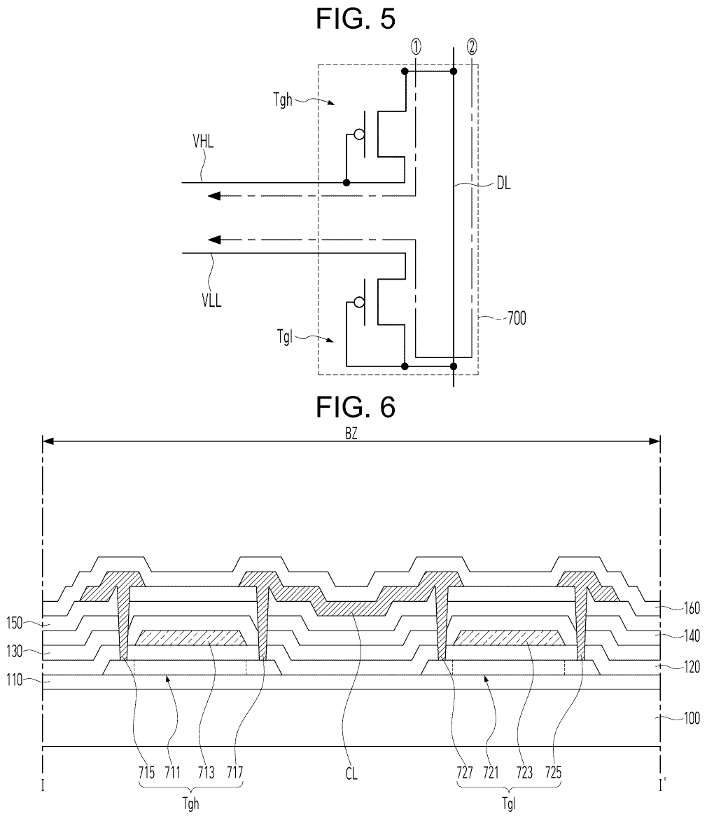

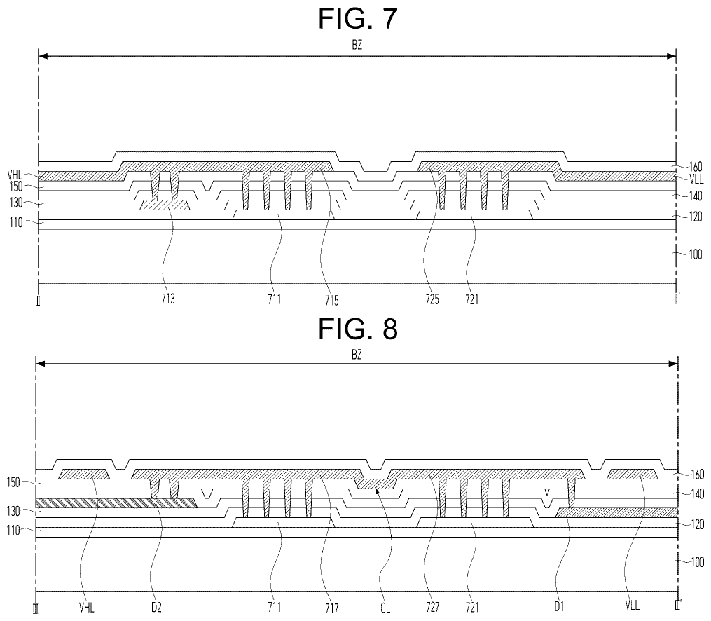

FIG. 4 is an enlarged view of the K1 region in FIG. 1. FIG. 5 is a view of an operative electro-static discharge circuit in the display apparatus. FIG. 6 is a view taken along I-I′ of FIG. 4. FIG. 7 is a view taken along II-II′ of FIG. 4. FIG. 8 is a view taken along III-III′ of FIG. 4. Referring to FIGS. 1 and 3 to 8, the display apparatus can include a plurality of electro-static discharge circuits 700 disposed between the display area AA and the pad area PAD. The plurality of electro-static discharge circuits 700 can be electrically connected to the data lines DL. For example, each of the data lines DL can be electrically connected to one of the electro-static discharge circuits 700. Thus, in the display apparatus according to the embodiment of the present disclosure, a static electricity applied to the display area AA through the data lines DL can be discharged by the electro-static discharge circuits 700. Therefore, the damage of the driving circuits DC and the light-emitting devices 500 in the display area AA due to the static electricity can be prevented.

Also, each of the electro-static discharge circuits 700 can be electrically connected to a high potential voltage wiring VHL and a low potential voltage wiring VLL, and each of the electro-static discharge circuits 700 can include a high potential ESD transistor Tgh electrically connected to the high potential voltage wiring VHL and a low potential ESD transistor Tgl electrically connected to the low potential voltage wiring VLL. It is to be appreciated static electricity can have a voltage higher than a high potential signal applied through the high potential voltage wiring VHL or a voltage lower than a low potential signal applied through the low potential voltage wiring VLL. It is also to be appreciated the gate signal and the data signal can have a voltage between the low potential signal and the high potential signal.

Also, the high potential ESD transistor Tgh can include a high potential semiconductor pattern 711, a high potential ESD gate electrode 713, a first high potential ESD electrode 715, and a second high potential ESD electrode 717. The high potential semiconductor pattern 711 can include a semiconductor material, such as low-temperature poly-Si (LTPS). The high potential semiconductor pattern 711 can also include a same material as the second semiconductor pattern 221 in each pixel area PA. The high potential semiconductor pattern 711 can be disposed on a same layer as the second semiconductor pattern 221 of each pixel area PA, and can be simultaneously formed by a same process as the second semiconductor pattern 221 of each pixel area PA. The high potential ESD gate electrode 713 can include a conductive material. For example, the high potential ESD gate electrode 713 can include a metal, such as aluminum (Al), chrome (Cr), copper (Cu), molybdenum (Mo), titanium (Ti), and tungsten (W). The high potential ESD gate electrode 713 can also include a same material as the second gate electrode 223 of each pixel area PA, can be disposed on a same layer as the second gate electrode 223 of each pixel area PA, and can be formed simultaneously by a same process as the second gate electrode 223 of each pixel area PA. The high potential ESD gate electrode 713 can also be electrically connected to the high potential voltage wiring VHL such that the high potential signal can be continuously applied to the high potential ESD gate electrode 713 through the high potential voltage wiring VHL.

Further, the high potential ESD gate electrode 713 can be disposed on a portion of the high potential semiconductor pattern 711 such that the high potential ESD gate electrode 713 overlaps a high potential channel region of the high potential semiconductor pattern 711. The high potential semiconductor pattern 711 can include a first high potential region and a second high potential region, which are disposed outside the high potential ESD gate electrode 713. Thus, the high potential channel region can be disposed between the first high potential region and the second high potential region. Also, a resistance of the first high potential region and a resistance of the second high potential region can be smaller than a resistance of the high potential channel region. For example, the first high potential region and the second high potential region can include a region doped with conductive impurities while the high potential channel region can be a region not doped with conductive impurities. The high potential ESD gate electrode 713 can be spaced apart from, and insulated from, the high potential semiconductor pattern 711.

Still further, the first high potential ESD electrode 715 can include a conductive material. For example, the first high potential ESD electrode 715 can include a metal, such as aluminum (Al), chrome (Cr), copper (Cu), molybdenum (Mo), titanium (Ti), and tungsten (W). The first high potential ESD electrode 715 can include a different material from the high potential ESD gate electrode 713, and can be disposed on a different layer from the high potential ESD gate electrode 713. The first high potential ESD electrode 715 can also be electrically connected to the first high potential region of the high potential semiconductor pattern 711, and can also be electrically connected to the high potential ESD gate electrode 713. Thus, the high potential signal can be continuously applied to the first high potential region of the high potential semiconductor pattern 711 through the high potential ESD gate electrode 713 and the first high potential ESD electrode 715.

Also, the second high potential ESD electrode 717 can include a conductive material. For example, the second high potential ESD electrode 717 can include a metal, such as aluminum (Al), chrome (Cr), copper (Cu), molybdenum (Mo), titanium (Ti), and tungsten (W). The second high potential ESD electrode 717 can include a different material from the high potential ESD gate electrode 713, and can be disposed on a different layer from the high potential ESD gate electrode 713. The second high potential ESD electrode 717 can also be disposed on a same layer as the first high potential ESD electrode 715, can include a same material as the first high potential ESD electrode 715, and can be formed simultaneously by a same process as the first high potential ESD electrode 715.

In addition, the second high potential ESD electrode 717 can be electrically connected to the second high potential region of the high potential semiconductor pattern 711. The second high potential ESD electrode 717 can also be spaced apart from the first high potential ESD electrode 715, and can be insulated from the high potential ESD gate electrode 713. The second high potential ESD electrode 717 can further be electrically connected to the corresponding data line DL. For example, the second high potential region of the high potential semiconductor pattern 711 can be electrically connected to the corresponding data line DL through the second high potential ESD electrode 717. Thus, the second high potential region of each electro-static discharge circuit 700 can have a voltage higher than the first high potential region of the corresponding electro-static discharge circuit 700, when static electricity having a higher voltage than the high potential signal is applied through the data line DL electrically connected to the corresponding electro-static discharge circuit 700. Thus, when a static electricity having higher voltage than the high potential signal is applied through one of the data lines DL, the high potential ESD transistor Tgh of the electro-static discharge circuit 700 electrically connected to the corresponding data line DL can be turned on. Therefore, static electricity (1) having a higher voltage than the high potential signal applied through one of the data line DL can be discharged by the high potential ESD transistor Tgh of the electro-static discharge circuit 700 electrically connected to the corresponding data line DL.

Also, the low potential ESD transistor Tgl can include a low potential semiconductor pattern 721, a low potential ESD gate electrode 723, a first low potential ESD electrode 725, and a second low potential ESD electrode 727. The low potential semiconductor pattern 721 can also include a semiconductor material, such as a low-temperature poly-Si (LTPS). The low potential semiconductor pattern 721 can include a same material as the high potential semiconductor pattern 711, can be disposed on a same layer as the high potential semiconductor pattern 711, and can be formed simultaneously by a same process as the high potential semiconductor pattern 711.

Further, the low potential ESD gate electrode 723 can include a conductive material. For example, the low potential ESD gate electrode 723 can include a metal, such as aluminum (Al), chrome (Cr), copper (Cu), molybdenum (Mo), titanium (Ti), and tungsten (W). The low potential ESD gate electrode 723 can also include a same material as the high potential ESD gate electrode 713, can be disposed on a same layer as the high potential ESD gate electrode 713, and can be formed simultaneously by a same process as the high potential ESD gate electrode 713. The low potential ESD gate electrode 723 can also be disposed on a portion of the low potential semiconductor pattern 721. For example, the low potential ESD gate electrode 723 can overlap a low potential channel region of the low potential semiconductor pattern 721. The low potential semiconductor pattern 721 can also include a first low potential region and a second low potential region, which are disposed outside the low potential ESD gate electrode 723, and the low potential channel region can be disposed between the first low potential region and the second low potential region. A resistance of the first low potential region and a resistance of the second low potential region can be smaller than a resistance of the low potential channel region, and the first low potential region and the second low potential region can include a region doped with conductive impurities. In contrast, the low potential channel region can be a region not doped with conductive impurities. The low potential ESD gate electrode 723 can be spaced apart from, and insulated from, the low potential semiconductor pattern 721.

Also, the first low potential ESD electrode 725 can include a conductive material. For example, the first low potential ESD electrode 725 can include a metal, such as aluminum (Al), chrome (Cr), copper (Cu), molybdenum (Mo), titanium (Ti), and tungsten (W). The first low potential ESD electrode 725 can also include a different material from the low potential ESD gate electrode 723. The first low potential ESD electrode 725 can also be disposed on a different layer from the low potential ESD gate electrode 723 while disposed on a same layer as the first high potential ESD electrode 715. The first low potential ESD electrode 725 can also be formed simultaneously by a same process as the first high potential ESD electrode 715. The first low potential ESD electrode 725 can be electrically connected to the first low potential region of the low potential semiconductor pattern 721 while insulated from the low potential ESD gate electrode 723. The first low potential ESD electrode 725 can also be electrically connected to the low potential voltage wiring VLL to allow the low potential signal to be continuously applied to the first low potential region of the low potential semiconductor pattern 721 through the first low potential ESD electrode 725.

In addition, the second low potential ESD electrode 727 can include a conductive material. For example, the second low potential ESD electrode 727 can include a metal, such as aluminum (Al), chrome (Cr), copper (Cu), molybdenum (Mo), titanium (Ti), and tungsten (W). The second low potential ESD electrode 727 can also include a different material from the low potential ESD gate electrode 723, and can be disposed on a different layer from the low potential ESD gate electrode 723. The second low potential ESD electrode 727 can also be disposed on a same layer as the first low potential ESD electrode 725, include a same material as the first low potential ESD electrode 725, and be formed simultaneously by a same process as the first low potential ESD electrode 725.

Also, the second low potential ESD electrode 727 can be electrically connected to the second low potential region of the low potential semiconductor pattern 721 as well as the low potential ESD gate electrode 723. The second low potential ESD electrode 727 can also be spaced apart from the first low potential ESD electrode 725. The second low potential ESD electrode 727 can be electrically connected to the corresponding data line DL. For example, the low potential ESD gate electrode 723 and the second low potential region of the low potential semiconductor pattern 721 can be electrically connected to the corresponding data line DL through the second low potential ESD electrode 727. Thus, in the display apparatus according to the embodiment of the present disclosure, the second low potential region of each electro-static discharge circuit 700 can have a voltage lower than the first low potential region of the corresponding electro-static discharge circuit 700, when static electricity having a lower voltage than the low potential signal is applied through the data line DL electrically connected to the corresponding electro-static discharge circuit 700. Also, when static electricity having a lower voltage than the low potential signal is applied to one of the data lines DL, a signal having a lower voltage than the low potential signal can be applied to the low potential ESD gate electrode 723 of the electro-static discharge circuit 700 electrically connected to the corresponding data line DL. Thus, the low potential ESD transistor Tgl of the electro-static discharge circuit 700 electrically connected to the corresponding data line DL can be turned on. Therefore, in the display apparatus according to the embodiment of the present disclosure, the static electricity (2) having a lower voltage than the low potential signal and applied through one of the data line DL can be discharged by the low potential ESD transistor Tgl of the electro-static discharge circuit 700 electrically connected to the corresponding data line DL.

Also, the above-mentioned plurality of inorganic insulating layer 110, 120, 130, 140, 150, and 160 disposed between the display area AA of the device substrate 100 and the lower planarization layer 170 can extend on the bezel area BZ of the device substrate 100. Accordingly, the high potential semiconductor pattern 711 and the low potential semiconductor pattern 721 of each electro-static discharge circuit 700 can be disposed between the lower buffer layer 110 and the lower gate insulating layer 120 of the bezel area BZ, and the high potential ESD gate electrode 713 and the low potential ESD gate electrode 723 of each electro-static discharge circuit 700 can be disposed between the lower gate insulating layer 120 and the lower interlayer insulating layer 130 of the bezel area BZ. Also, the first high potential ESD electrode 715, the second high potential ESD electrode 717, the first low potential ESD electrode 725, and the second low potential ESD electrode 727 of each electro-static discharge circuit 700 can be disposed on a same layer as the first drain electrode 215, the first source electrode 217, the second drain electrode 225, and the second source electrode 227 of each pixel area PA. In addition, the first high potential ESD electrode 715, the second high potential ESD electrode 717, the first low potential ESD electrode 725, and the second low potential ESD electrode 727 of each electro-static discharge circuit 700 can be disposed between the plurality of inorganic insulating layers 110, 120, 130, 140, 150 and 160. Further, the first high potential ESD electrode 715, the second high potential ESD electrode 717, the first low potential ESD electrode 725, and the second low potential ESD electrode 727 of each electro-static discharge circuit 700 can be disposed between the upper gate insulating layer 150 and the upper interlayer insulating layer 160 of the bezel area BZ. Thus, in the display apparatus according to the embodiment of the present disclosure, the first high potential ESD electrode 715, the second high potential ESD electrode 717, the first low potential ESD electrode 725 and the second low potential ESD electrode 727 of each electro-static discharge circuit 700 can be covered by the upper interlayer insulating layer 160.

Also, the high potential voltage wiring VHL and the low potential voltage wiring VLL can be disposed on a same layer as the first high potential ESD electrode 715, the second high potential ESD electrode 717, the first low potential ESD electrode 725 and the second low potential ESD electrode 727 of each electro-static discharge circuit 700. The high potential voltage wiring VHL and the low potential voltage wiring VLL can also include a same material as the first high potential ESD electrode 715, the second high potential ESD electrode 717, the first low potential ESD electrode 725, and the second low potential ESD electrode 727 of each electro-static discharge circuit 700. The high potential voltage wiring VHL and the low potential voltage wiring VLL can also be formed simultaneously by a same process as the first high potential ESD electrode 715, the second high potential ESD electrode 717, the first low potential ESD electrode 725, and the second low potential ESD electrode 727 of each electro-static discharge circuit 700. In addition, the first high potential ESD electrode 715 of each electro-static discharge circuit 700 can be in direct contact with the high potential voltage wiring VHL while the first low potential ESD electrode 725 of each electro-static discharge circuit 700 can be in direct contact with the low potential voltage wiring VLL. The high potential voltage wiring VHL and the low potential voltage wiring VLL can also be covered by the upper interlayer insulating layer 160 of the bezel area BZ. Thus, in the display apparatus according to the embodiment of the present disclosure, a process of forming the high potential voltage wiring VHL and the low potential voltage wiring VLL can be simplified.

Furthermore, a space between the ESD electrodes 715, 717, 725, and 727 having a potential difference in each electro-static discharge circuit 700 and a space between the ESD electrode 715, 717, 725, and 727 and the voltage wiring VHL and VLL, which are electrically disconnected, can be filled with an inorganic insulating material. For example, in the display apparatus according to the embodiment of the present disclosure, a space between the second high potential ESD electrode 717 of each electro-static discharge circuit 700 and the high potential voltage wiring VHL, a space between the second low potential ESD electrode 727 of each electro-static discharge circuit 700 and the low potential voltage wiring VLL, and a space between the first high potential ESD electrode 715 and the first low potential ESD electrode 725 of each electro-static discharge circuit 700 can be filled by the upper interlayer insulating layer 160. Thus, in the display apparatus according to the embodiment of the present disclosure, the penetration of moisture and oxygen through the space between the ESD electrodes 715, 717, 725 and 727 having a potential difference in each electro-static discharge circuit 700 and the space between the ESD electrode 715, 717, 725 and 727 and the voltage wiring VHL and VLL, which are electrically disconnected can be prevented. Therefore, in the display apparatus according to the embodiment of the present disclosure, an electrolytic corrosion reaction between the ESD electrodes 715, 717, 725, and 727 having a potential difference in each electro-static discharge circuit 700 and between the ESD electrode 715, 717, 725, and 727 and the voltage wiring VHL and VLL, which are electrically disconnected can be suppressed. Thus, the damage of the high potential voltage wiring VHL, the low potential voltage wiring VLL, the first high potential ESD electrodes 715, the second high potential ESD electrodes 717, the first low potential ESD electrodes 725, and the second low potential ESD electrodes 727 due to oxidization or deoxidization can be prevented.

Accordingly, the display apparatus can include the electro-static discharge circuits 700 disposed between the display area AA and the pad area PAD in which the high potential ESD transistor Tgh and the low potential ESD transistor Tgl of each electro-static discharge circuit 700 electrically connected to one of the data lines DL can include the ESD gate electrode 713 and 723, the first ESD electrode 715 and 725, and the second ESD electrode 717 and 727 disposed between the inorganic insulating layers 110, 120, 130, 140, 150, and 160 of the bezel area BZ in which the high potential voltage wiring VHL and the low potential voltage wiring VLL electrically connected to each electro-static discharge circuit 700 can be disposed between the inorganic insulating layers 110, 120, 130, 140, 150 and 160 of the bezel area BZ. Thus, in the display apparatus according to the embodiment of the present disclosure, the high potential ESD transistor Tgh and the low potential ESD transistor Tgl of each electro-static discharge circuit 700 can't be damaged by the electrolytic corrosion reaction. Accordingly, the damage of the electro-static discharge circuits due to moisture and oxygen can be prevented. Therefore, the decrease in the lifespan of the driving circuits DC and the light-emitting devices 500 duc to the static electricity can be prevented.

While the high potential ESD transistor Tgh and the low potential ESD transistor Tgl of each electro-static discharge circuit 700 shown in FIG. 5 are P-type transistors, in other embodiments N-type transistors can be used so long as the gate of the high potential ESD transistor Tgh is connected to the data line DL and the gate of the low potential ESD transistor Tgl is connected to the low potential voltage wiring VLL. Also, while the high potential semiconductor pattern 711 and the low potential semiconductor pattern 721 as shown to be spaced apart, in other embodiments the high potential semiconductor pattern 711 and the low potential semiconductor pattern 721 can be one integrally-formed pattern with the connecting portion of the high potential semiconductor pattern 711 and the low potential semiconductor pattern 721 doped to be highly conductive.

Further, in other embodiments the high potential semiconductor pattern 711 and the low potential semiconductor pattern 721 can be formed on the top surface of the upper buffer layer 140, which would allow the high potential ESD transistor Tgh and the low potential ESD transistor Tgl to be formed with the same processes as the first thin film transistor TR1 shown in FIG. 3. This embodiment could also be accompanied with a light-shielding electrode below the high potential semiconductor pattern 711 and the low potential semiconductor pattern 721 that could be disposed in a same process as is used to make the first capacitor electrode 231 or the second capacitor electrode 232. In addition, the added light-shielding electrodes could act as second/lower gate electrode which could be electrically connected to the respective gate electrodes of the high potential ESD transistor Tgh and the low potential ESD transistor Tgl. The added light-shielding electrodes could also be electrically connected to any constant voltage source or programmable voltage source to fine-tune threshold voltages for the high potential ESD transistor Tgh and the low potential ESD transistor Tgl.

Still further, in yet other embodiments one of the high potential semiconductor pattern 711 and the low potential semiconductor pattern 721 can be formed on the top surface of the lower buffer layer 110, while the other of the high potential semiconductor pattern 711 and the low potential semiconductor pattern 721 can be formed on the top surface of the upper buffer layer 140. In such embodiments, this configuration could allow one of the high potential semiconductor pattern 711 and the low potential semiconductor pattern 721 to be formed of an N-type semiconductor with the other of the high potential semiconductor pattern 711 and the low potential semiconductor pattern 721 formed of a P-type semiconductor. For example, referring to FIG. 5, the high potential ESD transistor Tgh can be a P-type transistor and the low potential ESD transistor Tgl is an N-type transistor assuming that the gate of the low potential ESD transistor Tgl is electrically connected to the low potential voltage wiring VLL. Similarly, the high potential ESD transistor Tgh can be an N-type transistor and the low potential ESD transistor Tgl is a P-type transistor assuming that the gate of the high potential ESD transistor Tgh is electrically connected to the data line DL.

In addition, the electro-static discharge circuits 700 can be formed using a process of forming the driving circuit DC of each pixel area PA. Thus, decrease in the process efficiency due to a process of forming the electro-static discharge circuits 700 can be prevented. Therefore, in the display apparatus according to the embodiment of the present disclosure, the production energy can be reduced by the process optimization.

Further, each of the data lines DL can include a first line region D1 disposed close to the pad area PAD, a second line region D2 disposed close to the display area AA, and a connection region CL disposed between the first line region D1 and the second line region D2. Also, the high potential ESD transistor Tgh and the low potential ESD transistor Tgl of each electro-static discharge circuit 700 can be electrically connected to the connection region CL of the data line DL electrically connected to the corresponding electro-static discharge circuit 700. For example, in the display apparatus according to the embodiment of the present disclosure, the connection region CL of each data line DL can be disposed on a same layer as the second high potential ESD electrode 717 and the second low potential ESD electrode 727 of each electro-static discharge circuit 700, as shown in FIGS. 4, 6, and 8. The connection region CL of each data line DL can further be disposed between the upper gate insulating layer 150 and the upper interlayer insulating layer 160, and can include a same material as the second high potential ESD electrode 717 and the second low potential ESD electrode 727 of each electro-static discharge circuit 700. Also, the second high potential ESD electrode 717 and the second low potential ESD electrode 727 of each electro-static discharge circuit 700 can be in direct contact with the connection region CL of the corresponding data line DL, and the connection region CL of each data line DL can include a region functioning as the second high potential ESD electrode 717 of the electro-static discharge circuit 700 electrically connected to the corresponding data line DL and a region functioning as the second low potential ESD electrode 727 of the electrode static discharge circuit 700 electrically connected to the corresponding data line DL. Thus, in the display apparatus according to the embodiment of the present disclosure, the process efficiency can be improved.

In the present embodiment, the first line region D1 and the second line region D2 of each data line DL can be disposed on a same layer as the connection region CL of the corresponding data line DL. However, in the display apparatus according to another embodiment of the present disclosure, the first line region D1 and the second line region D2 of each data line DL can be disposed on a different layer from the connection region CL of the corresponding data line DL. For example, in the display apparatus according to another embodiment of the present disclosure, the first line region D1 of each data line DL can be disposed between the lower gate insulating layer 120 and the lower interlayer insulating layer 130, and the second line region D2 of each data line DL can be disposed between the lower interlayer insulating layer 130 and the upper buffer layer 140, as shown in FIG. 8.

Further, the first line region D1 of each data line DL can be disposed on a same layer as the second gate electrode 223 of each pixel area PA, and the second line region D2 of each data line DL can be disposed on a same layer as the second capacitor electrode 232 of each pixel area PA. The first line region D1 of each data line DL can include a same material as the second gate electrode 223 of each pixel area PA, and the second line region D2 of each data line DL can include a same material as the second capacitor electrode 232 of each pixel area PA. The first line region D1 of each data line DL can be formed simultaneously by a same process as the second gate electrode 223 of each pixel area PA, and the second line region D2 of each data line DL can be formed simultaneously by a same process as the second capacitor electrode 232 of each pixel area PA. Thus, in the display apparatus according to another embodiment of the present disclosure, the process efficiency can be improved.

In addition, the presently disclosed driving circuit DC consists of the first thin film transistor TR1, the second thin film transistor TR2, and the storage capacitor Cst. However, in the display apparatus according to another embodiment of the present disclosure, the driving circuit DC can include a driving thin film transistor and at least one switching thin film transistor. For example, in the display apparatus according to another embodiment of the present disclosure, the driving circuit DC can further include a third thin film transistor to initialize the storage capacitor Cst of the corresponding pixel area PA according to the gate signal. The third thin film transistor can include a third semiconductor pattern, a third gate electrode, a third drain electrode, and a third source electrode. The third semiconductor pattern can include a semiconductor material, and the third gate electrode can be electrically connected to one of the gate lines GL. The third drain electrode can be electrically connected to an initial line applying an initial signal, and the third source electrode can be electrically connected to the storage capacitor Cst of the corresponding pixel area PA. Thus, in the display apparatus according to another embodiment of the present disclosure, the degree of freedom in the configuration of the driving circuit DC in each pixel area PA can be improved.

In addition, the location and the electric connection of the first drain electrode, the first source electrode, the second drain electrodes 225, and the second source electrode 227 of each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of each thin film transistor TR1 and TR2 can be improved.

Also, while the presently described second semiconductor pattern 221 of the second thin film transistor TR2 electrically connected to the light-emitting device 500 in each pixel area PA includes a low-temperature poly-Si (LTPS), in other embodiments the first transmission areas TI can function as a driving thin film transistor of the corresponding pixel area PA while the second gate electrode 223 can be electrically connected to the corresponding gate line GL, the second drain electrode 225 can be electrically connected to the corresponding data line DL, and the first electrode 510 can be electrically connected to the first source electrode 217. Thus, the semiconductor pattern 211 and 221 of thin film transistors TR1 and TR2 functioning as a driving thin film transistor in each pixel area PA can include an oxide semiconductor, such as IGZO. Therefore, in the display apparatus according to another embodiment of the present disclosure, the degree of freedom in the configuration of the driving circuit DC in each pixel area PA can be improved.

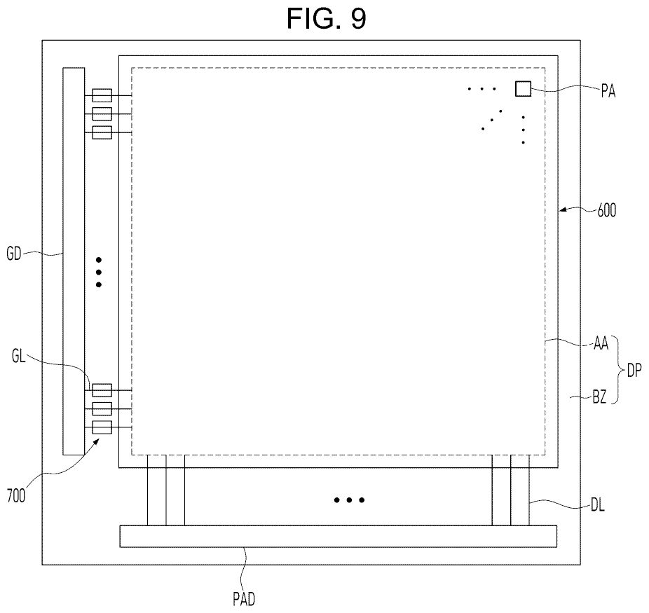

In addition, while each of the presently described data lines DL is electrically connected to one of the electro-static discharge circuits 700, in other embodiments, at least one of the signal wirings GL, DL, and PL electrically connected to the driving circuit DC can be electrically connected to the electro-static discharge circuits 700. For example, each of the electro-static discharge circuits 700 can be electrically connected to one of the gate lines GL as shown in FIG. 9. Thus, in the display apparatus according to another embodiment of the present disclosure, the damage of the electro-static discharge circuits 700 blocking a static electricity applied to the display area AA through the gate lines GL due to moisture and oxygen can be prevented. Therefore, in the display apparatus according to another embodiment of the present disclosure, the decrease in the lifespan of the driving circuits DC and the light-emitting devices 500 due to a static electricity can be prevented.

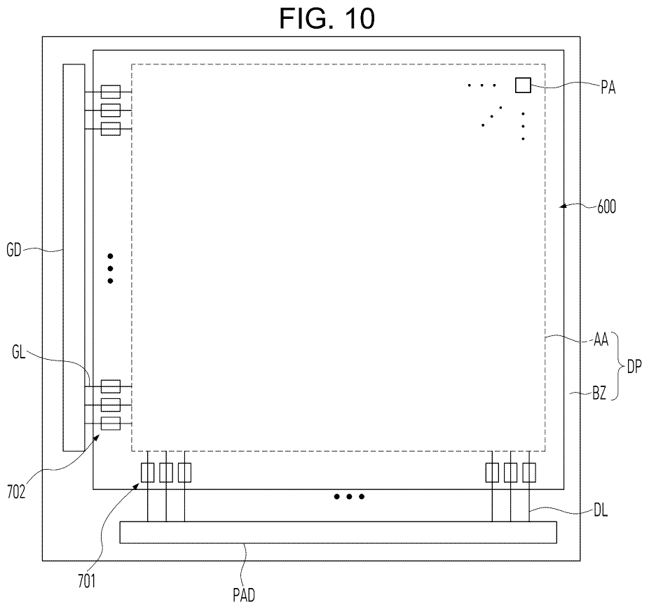

Also, the presently disclosed electro-static discharge circuits 700 are disposed outside the encapsulation structure 600. However, in other embodiments, the electro-static discharge circuits 700 can be arranged on various locations. For example, in the display apparatus according to another embodiment of the present disclosure, each of the data lines DL can be electrically connected to one of first electro-static discharge circuits 701 between the pad area PAD and the display area AA, each of the gate lines GL can be electrically connected to one of second electro-static discharge circuits 702 between the gate driver GD and the display area AA, and the first electro-static discharge circuits 701 and the second electro-static discharge circuits 702 can overlap the encapsulation structure 600, as shown in FIG. 10. Thus, in the display apparatus according to another embodiment of the present disclosure, the degree of freedom in the location of the first electro-static discharge circuits 701 and the location of the second electro-static discharge circuits 702 can be improved. Therefore, in the display apparatus according to another embodiment of the present disclosure, the decrease in the lifespan of the driving circuits DC and the light-emitting devices 500 due to a static electricity can be effectively prevented.

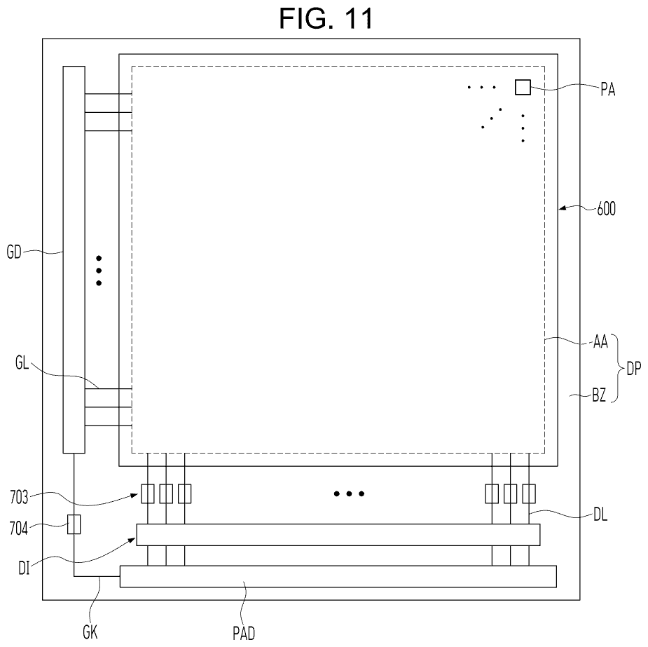

Further, according to another embodiment of the present disclosure, an IC area D1 in which a driver IC is mounted can be disposed between the pad area PAD and the display area AA, each of the data lines DL can be electrically connected to one of first electro-static discharge circuits 703 disposed between the IC area D1 and the display area AA, and a gate link line GK connecting between the pad area PAD, and the gate driver GD can be electrically connected to a second electro-static discharge circuit 704, as shown in FIG. 11. Thus, in the display apparatus according to another embodiment of the present disclosure, the degree of freedom in the configuration of the bezel area BZ can be improved.

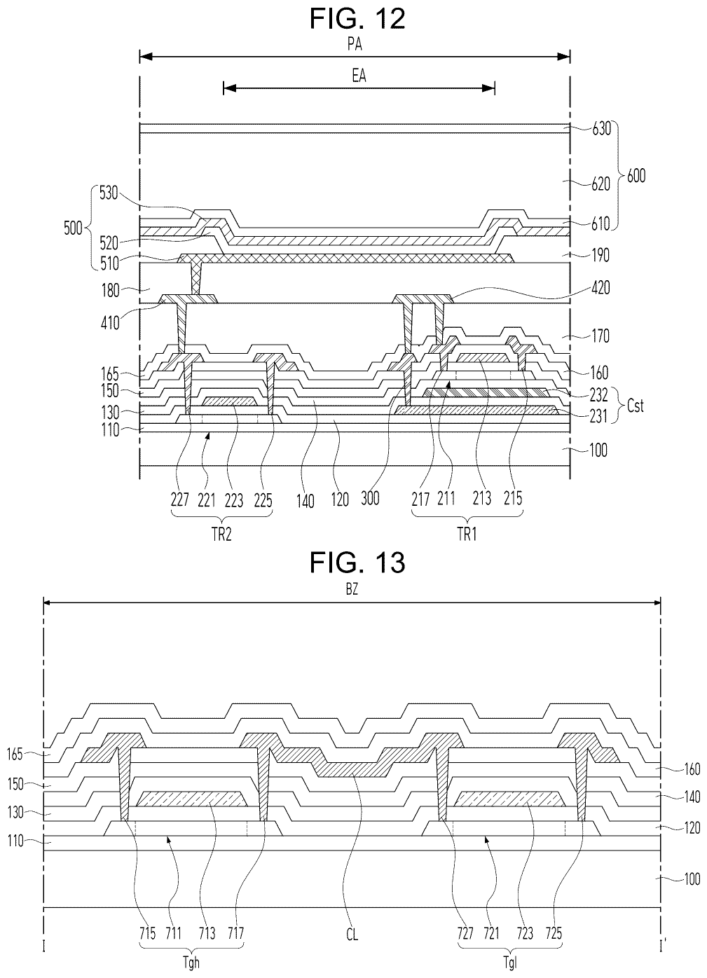

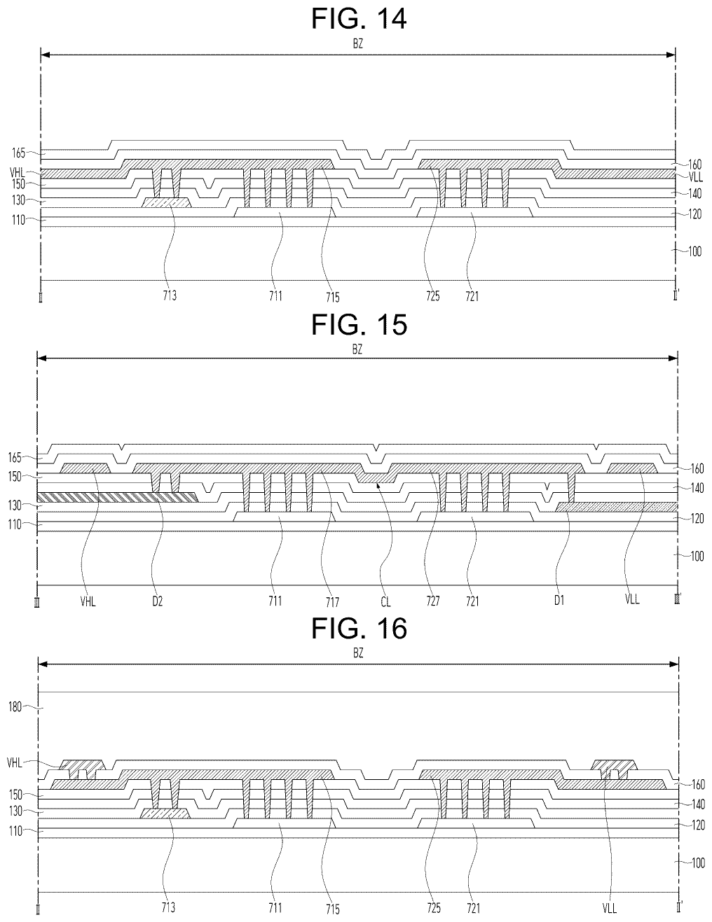

Still further, the presently described first thin film transistor TR1 and the second thin film transistor TR2 are covered by the lower planarization layer 170. However, in other embodiments, the first drain electrode 215, the first source electrode 217, the second drain electrode 225, and the second source electrode 227 can be covered by an inorganic insulating layer made of an inorganic insulating material. Further, a device passivation layer 165 can be disposed between the upper interlayer insulating layer 160 and the lower planarization layer 170, and the first drain electrode 215, the first source electrode 217, the second drain electrode 225, and the second source electrode 227 can be disposed between the upper interlayer insulating layer 160 and the device passivation layer 165, as shown in FIGS. 12 to 15.

Further, the device passivation layer 165 can extend on the bezel area BZ, and the upper interlayer insulating layer 160 and the device passivation layer 165 can be stacked on the first high potential ESD electrode 715, the second high potential ESD electrode 717, the first low potential ESD electrode 725, and the second low potential ESD electrode 727 of each electro-static discharge circuit. Thus, the electrolytic corrosion reaction of the high potential ESD transistor Tgh and the low potential ESD transistor Tgl constituting each electro-static discharge circuit can be effectively suppressed. In addition, the electrolytic corrosion reaction between the first drain electrode 215, the first source electrode 217, the second drain electrode 225, and the second source electrode 227 can be suppressed. Therefore, in the display apparatus according to another embodiment of the present disclosure, the reliability and the lifespan can be improved.

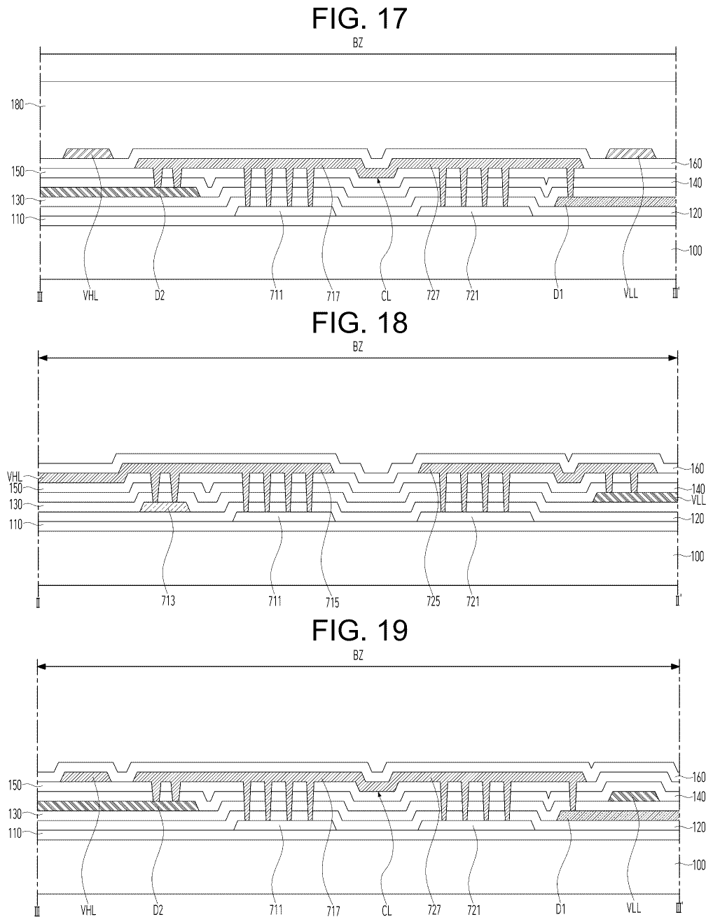

Still further, the presently described high potential voltage wiring VHL and the low potential voltage wiring VLL are disposed on a same layer as the first high potential ESD electrode 715, the second high potential ESD electrode 717, the first low potential ESD electrode 725, and the second low potential ESD electrode 727 of each electro-static discharge circuit 700. However, in other embodiments the high potential voltage wiring VHL and the low potential voltage wiring VLL can be disposed on various layers. For example, the upper planarization layer 180 can extend on the bezel area BZ, and the high potential voltage wiring VHL and the low potential voltage wiring VLL can be disposed between the upper interlayer insulating layer 160 and the upper planarization layer 180, as shown in FIGS. 16 and 17. Thus, spaces between the second high potential ESD electrode 717 of each electro-static discharge circuit and the high potential voltage wiring VHL, between the second low potential ESD electrode 727 of each electro-static discharge circuit and the low potential voltage wiring, and between the first high potential ESD electrode 715 and the first low potential ESD electrode 725 of each electro-static discharge circuit can be filled by the upper interlayer insulating layer 160. Thus, the electrolytic corrosion reaction between the second high potential ESD electrode 717 of each electro-static discharge circuit and the high potential voltage wiring VHL, between the second low potential ESD electrode 727 of each electro-static discharge circuit and the low potential voltage wiring, and between the first high potential ESD electrode 715 and the first low potential ESD electrode 725 of each electro-static discharge circuit can be suppressed by the upper interlayer insulating layer 160. Therefore, in the display apparatus according to another embodiment of the present disclosure, the degree of freedom in the location of the high potential voltage wiring VHL and the location of the low potential voltage wiring VLL can be improved.

In addition, the presently described low potential voltage wiring VLL is disposed on a same layer as the high potential voltage wiring VHL. However, in other embodiments the low potential voltage wiring VLL can be disposed on a different layer from the high potential voltage wiring VHL. For example, in the display apparatus according to another embodiment of the present disclosure, the low potential voltage wiring VLL crossing the first line region D1 of each data line can be disposed between the lower interlayer insulating layer 130 and the upper buffer layer 140, as shown in FIGS. 18 and 19. The low potential voltage wiring VLL can also be disposed on a same layer as the second line region D2 of each data line as well as disposed on a same layer as the second capacitor electrode of each pixel area. Also, the low potential voltage wiring VLL can include a same material as the second capacitor electrode of each pixel area, and can be formed simultaneously by a same process as the second capacitor electrode of each pixel area. Thus, in the display apparatus according to another embodiment of the present disclosure, the degree of freedom in the location of the low potential voltage wiring VLL can be improved.

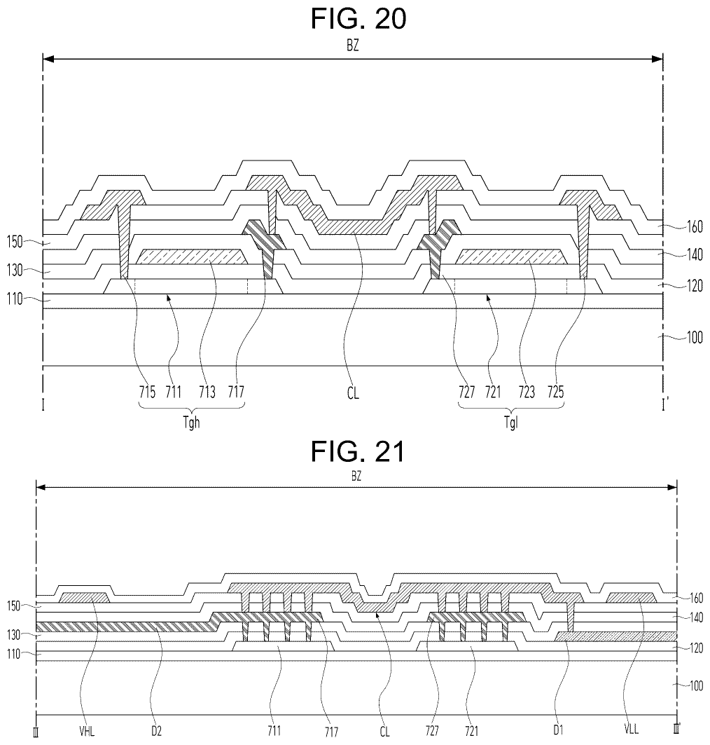

Further, the presently described second high potential ESD electrode 717 and the second low potential ESD electrode 727 of each electro-static discharge circuit 700 are disposed on a same layer as the first high potential ESD electrode 715 and the first low potential ESD electrode 725 of the corresponding electro-static discharge circuit 700. However, in other embodiments the second high potential ESD electrode 717 and the second low potential ESD electrode 727 of each electro-static discharge circuit 700 can be disposed on a different layer from the first high potential ESD electrode 715 and the first low potential ESD electrode 725 of the corresponding electro-static discharge circuit 700. For example, in the display apparatus according to another embodiment of the present disclosure, the first high potential ESD electrode 715 and the first low potential ESD electrode 725 of each electro-static discharge circuit can be disposed between the upper gate insulating layer 150 and the upper interlayer insulating layer 160, and the second high potential ESD electrode 717 and the second low potential ESD electrode 727 of each electro-static discharge circuit can be disposed between the lower interlayer insulating layer 130 and the upper buffer layer 140, as shown in FIGS. 20 and 21. Also, the second high potential ESD electrode 717 and the second low potential ESD electrode 727 of each electro-static discharge circuit can be disposed on a same layer as the second line region D2 of each data line, and the second high potential ESD electrode 717 of each electro-static discharge circuit can be in direct contact with the second line region D2 of the data line electrically connected to the corresponding electro-static discharge circuit. Thus, in the display apparatus according to another embodiment of the present disclosure, the degree of freedom in the configuration of the high potential ESD transistor Tgh and the configuration of the low potential ESD transistor Tgl constituting each electro-static discharge circuit can be improved.

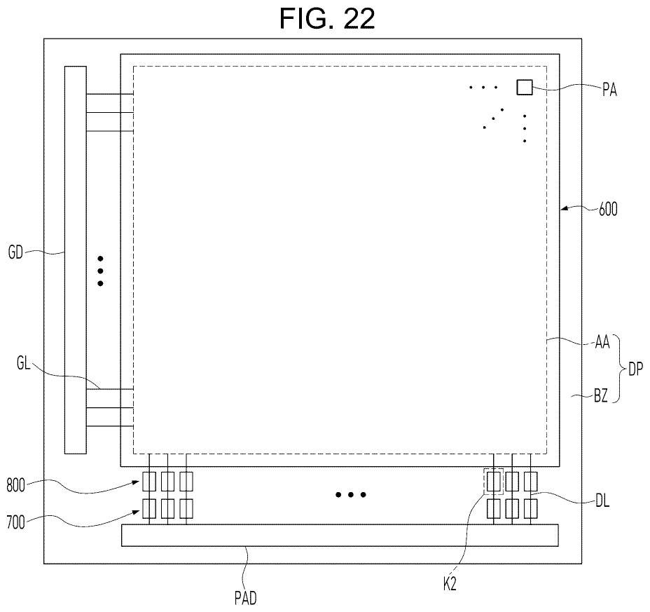

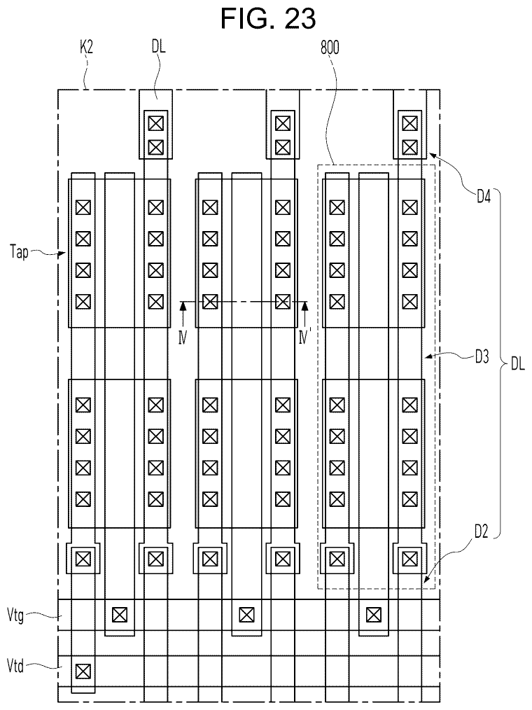

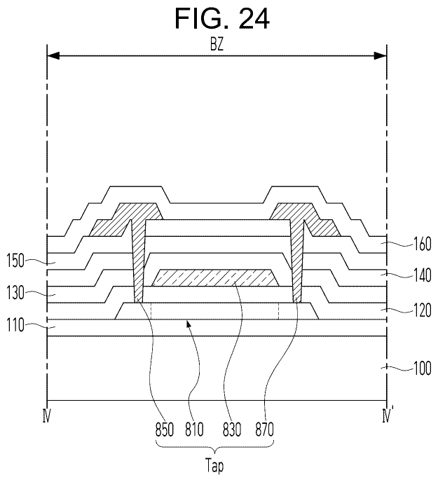

Still further, a plurality of test circuits 800 can be disposed between the pad area PAD and display area AA, as shown in FIGS. 22 to 24. FIG. 23 is an enlarged view of K2 region in FIG. 22. FIG. 24 is a view taken along IV-IV′ of FIG. 23. Each of the data lines DL can be electrically connected to one of the test circuits 800. The plurality of test circuits 800 can also be disposed between the electro-static discharge circuits 700 and the display area AA, and each of the data lines DL can include a third line region D3 and a fourth line region D4. The third line region D3 of each data line DL can be disposed between the second line region D2 and the fourth line region D4 of the corresponding data line DL, and each of the test circuits 800 can be electrically connected to the third line region D3 of one of the data lines DL between the second line region D2 and the fourth line region D4 of the corresponding data line DL. Also, the fourth line region D4 of each data line DL can be disposed between the corresponding test circuit 800 and the display area AA. For example, the driving circuit can be electrically connected to the fourth line region D4 of the corresponding data line DL.

Also, each of the test circuit 800 can include at least one test transistor Tap. The test transistor Tap can include a test semiconductor pattern 810, a test gate electrode 830, a first test electrode 850, and a second test electrode 870. For example, the test gate electrode 830 can be electrically connected to a test gate line Vtg applying a test gate signal, the first test electrode 850 can be electrically connected a test voltage wiring Vtd supplying a test voltage, and the second test electrode 870 of the test transistor Tap can be electrically connected to the data line DL. The test semiconductor pattern 810 can also include a semiconductor pattern. The test semiconductor pattern 810 can be disposed on a same layer as the high potential semiconductor pattern and the low potential semiconductor pattern. For example, the test semiconductor pattern 810 can be disposed between the lower buffer layer 110 and the lower gate insulating layer 120. The test semiconductor pattern 810 can include a same material as the high potential semiconductor pattern and the low potential semiconductor pattern. For example, the test semiconductor pattern 810 can include low-temperature poly-Si (LTPS).

Also, the test gate electrode 830 can be disposed on the high potential ESD gate electrode and the low potential ESD gate electrode. For example, the test gate electrode 830 can be disposed between the lower gate insulating layer 120 and the lower interlayer insulating layer 130. The test gate electrode 830 can also include a same material as the high potential ESD gate electrode and the low potential ESD gate electrode.

In addition, the first test electrode 850 and the second test electrode 870 can be disposed on a same layer as the first high potential ESD electrode, the second high potential ESD electrode, the first low potential ESD electrode, and the second low potential ESD electrode. The first test electrode 850 and the second test electrode 870 can further be disposed between the upper gate insulating layer 150 and the upper interlayer insulating layer 160, and can include a same material as the first high potential ESD electrode, the second high potential ESD electrode, the first low potential ESD electrode and the second low potential ESD electrode. Thus, in the display apparatus according to another embodiment of the present disclosure, the test gate electrode 830, the first test electrode 850 and the second test electrode 870 constituting the test transistor Tap of each test circuit 800 can be disposed between the plurality of inorganic insulating layers 110, 120, 130, 140, 150, and 160 stacked on the bezel area BZ. Therefore, in the display apparatus according to another embodiment of the present disclosure, the damage of the test transistor Tap due to a static electricity can be prevented.

Thus, the display apparatus according to the embodiments of the present disclosure can include the electro-static discharge circuit (ESD) on the bezel area in which the electro-static discharge circuit can include the ESD transistor, and wherein the ESD gate electrode, the first ESD electrode and the second ESD electrode of the ESD transistor can be covered by the inorganic insulating layer. Thus, the electrolytic corrosion reaction of the ESD gate electrode, the first ESD electrode, and the second ESD electrode due to moisture and oxygen can be suppressed. Thereby, in the display apparatus according to the embodiments of the present disclosure, the damage of the electro-static discharge circuit due to moisture and oxygen can be prevented. Also, the production energy can be reduced by the process optimization.

What is claimed is:

1. A display apparatus comprising:
a device substrate having a display area and a bezel area surrounding the display area, wherein the display area includes a plurality of pixel areas;
an organic insulating layer disposed on the display area of the device substrate;
a plurality of inorganic insulating layers disposed between the device substrate and the organic insulating layer, the plurality of inorganic insulating layers extending from the display area to on the bezel area of the device substrate;
a plurality of signal wirings disposed between the device substrate and the organic insulating layer, the plurality of signal wirings extending from respective pixel areas to the bezel area of the device substrate; and
an electro-static discharge (ESD) circuit on the bezel area, the electro-static discharge circuit including a first ESD transistor electrically connected to a second ESD transistor and a signal wiring of the plurality of signal wiring, and
wherein the first ESD transistor includes an ESD gate electrode, a first ESD electrode, and a second ESD electrode disposed between the plurality of inorganic insulating layers.

2. The display apparatus according to claim 1, wherein the second ESD electrode is disposed on a same layer as the first ESD electrode.

3. The display apparatus according to claim 1, further comprising a first voltage wiring on the bezel area,
wherein the first voltage wiring is electrically connected to the first ESD electrode, and
wherein the signal wiring of plurality of signal wirings is disposed on a different layer from the first ESD electrode and the second ESD electrode.

4. The display apparatus according to claim 3, wherein the plurality of inorganic insulating layers is disposed between the device substrate and the first voltage wiring.

5. The display apparatus according to claim 1, further comprising a driving circuit disposed between the device substrate and the organic insulating layer,
wherein the driving circuit is in a pixel area overlapping the display area,
wherein a first thin film transistor of the driving circuit includes a first gate electrode disposed on a same layer as the ESD gate electrode, and
wherein a first drain electrode and a first source electrode of the first thin film transistor are disposed on a different layer from the first ESD electrode and the second ESD electrode.

6. The display apparatus according to claim 5, wherein a first semiconductor pattern of the first thin film transistor is disposed on a same layer as an ESD semiconductor pattern of the first ESD transistor.

7. The display apparatus according to claim 5, wherein the first drain electrode and the first source electrode are disposed between the plurality of inorganic insulating layers and the organic insulating layer.

8. The display apparatus according to claim 5, wherein a second thin film transistor of the driving circuit includes a second gate electrode disposed on a different layer from the first gate electrode,
wherein a second drain electrode and a second source electrode of the second thin film transistor are disposed on a same layer as the first drain electrode and the first source electrode, and
wherein a second semiconductor pattern of the second thin film transistor is disposed on a different layer from a first semiconductor pattern of the first thin film transistor.

9. The display apparatus according to claim 1, wherein the second ESD transistor includes an ESD gate electrode, a first ESD electrode, and a second ESD electrode disposed between the plurality of inorganic insulating layers, and
wherein the second ESD electrode of the first ESD transistor is electrically connected to the second ESD electrode of the second ESD transistor and to the signal wiring of the plurality of signal wiring.

10. The display apparatus according to claim 9, further comprising a first voltage wiring and a second voltage wiring on the bezel area,
wherein the first ESD electrode of the first ESD transistor is electrically connected to the first voltage wiring, and
wherein the first ESD electrode of the second ESD transistor is electrically connected to the second voltage wiring.

11. The display apparatus according to claim 1, wherein the first ESD transistor includes a first semiconductor pattern with the ESD gate electrode of the first ESD transistor overlapping a channel region of the first semiconductor pattern, and
wherein first ESD electrode of the first ESD transistor contacts the first semiconductor pattern at multiple locations via multiple contact holes in multiple inorganic insulating layers.

12. A display apparatus, comprising:
a light-emitting device on a display area of a device substrate;
a driving circuit on the display area, the driving circuit electrically connected to the light-emitting device;
a signal wiring electrically connected to the driving circuit, the signal wiring extending on a bezel area of the device substrate;
an electro-static discharge circuit on the bezel area, the electro-static discharge circuit including a high potential ESD transistor and a low potential ESD transistor;
a high potential voltage wiring electrically connected to a first high potential ESD electrode of the high potential ESD transistor; and
a low potential voltage wiring electrically connected to a first low potential ESD electrode of the low potential ESD transistor,
wherein a second high potential ESD electrode of the high potential ESD transistor and a second low potential ESD electrode of the low potential ESD transistor are electrically connected to the signal wiring, and
wherein a first inorganic insulating layer is disposed between the second high potential ESD electrode and the high potential voltage wiring, between the second low potential ESD electrode and the low potential voltage wiring, and between the first high potential ESD electrode and the first low potential ESD electrode.

13. The display apparatus according to claim 12, wherein the second high potential ESD electrode and the second low potential ESD electrode are disposed on a different layer from the signal wiring.

14. The display apparatus according to claim 12, wherein the low potential voltage wiring is disposed on a same layer as the high potential voltage wiring.

15. The display apparatus according to claim 14, wherein the first high potential ESD electrode and the first low potential ESD electrode are disposed on a same layer as the high potential voltage wiring and the low potential voltage wiring.

16. The display apparatus according to claim 12, further comprising:
an organic insulating layer disposed between the driving circuit and the light-emitting device; and
a second inorganic insulating layer disposed between the device substrate and the organic insulating layer,
wherein the second inorganic insulating layer includes a same material as the first inorganic insulating layer.

17. The display apparatus according to claim 16, wherein the driving circuit includes a plurality of thin film transistors, and
wherein a drain electrode and a source electrode of some of the thin film transistors are disposed between the second inorganic insulating layer and the organic insulating layer.

18. The display apparatus according to claim 12, further comprising a pad area disposed in the bezel area,
wherein the electro-static discharge circuit is disposed between the display area and the pad area.

19. The display apparatus according to claim 12, wherein the high potential ESD gate electrode of the high potential ESD transistor is electrically connected to the high potential voltage wiring, and
wherein the low potential ESD gate electrode of the low potential ESD transistor is electrically connected to the signal wiring.

20. The display apparatus according to claim 19, wherein the second low potential ESD electrode of the low potential ESD transistor is electrically connected to the low potential ESD gate electrode of the low potential ESD transistor.
